(19) United States
(12) Patent Application Publication
(10) Pub. No.: US 2023/0420332 A1
(43) Pub. Date: Dec. 28, 2023

(54) INTEGRATED DEVICE DIE WITH THERMAL CONNECTION

(71) Applicant: Skyworks Solutions, Inc., Irvine, CA (US)

(72) Inventors: Guillaume Alexandre Blin, Carlisle, MA (US); Nakul Kothari, Irvine, CA (US); Leslie Paul Wallis, Ottawa (CA)

(21) Appl. No.: 18/213,200

(22) Filed: Jun. 22, 2023

Related U.S. Application Data
(60) Provisional application No. 63/367,194, filed on Jun. 28, 2022.
(60) Provisional application No. 63/367,187, filed on Jun. 28, 2022.

(51) Int. Cl. H01L 23/367; H01L 23/373

(52) U.S. Cl. CPC H01L 23/3677; H01L 23/373

(57) ABSTRACT

An integrated device die is disclosed. The integrated device die can include a substrate having a first side and a second side opposite the first side, a heat generating electronic component disposed over the first side of the substrate, a dielectric layer disposed such that the heat generating electronic component is positioned at least partially between the substrate and the dielectric layer. A surface of the dielectric layer that faces away from the substrate includes a terminal that is electrically connected to the heat generating electronic component and is laterally offset from the heat generating electronic component. The thermally conductive structure is positioned between the substrate and the terminal. The substrate and the thermally conductive structure at least partially define a thermal pathway between the heat generating electronic component and the terminal.

### INCORPORATION BY REFERENCE TO ANY PRIORITY APPLICATIONS

Any and all applications for which a foreign or domestic priority claim is identified in the Application Data Sheet as filed with the present application, including U.S. Provisional Patent Application No. 63/367,194, filed Jun. 28, 2022, titled “INTEGRATED DEVICE DIE WITH THERMAL CONNECTION,” and U.S. Provisional Patent Application No. 63/367,187, filed Jun. 28, 2022, titled “ELECTRICALLY ISOLATED THERMAL CONNECTION IN INTEGRATED DEVICE DIE” are hereby incorporated by reference under 37 CFR 1.57 in their entirety.

### BACKGROUND

### Technical Field

Embodiments of this disclosure relate to a thermal connection in an integrated device die.

### Description of Related Technology

An electronic component included in an integrated device die can generate heat during operations. The heat generated by the active device can cause various issues. For example, the heat can negatively impact reliability of the integrated device die, limit an operating range of the integrated device die, impacts other components in a system or device that the integrated device die is included, limit a modulation order and data rate, negatively impact performance (e.g., lower grain, higher leakage, etc.) of the integrated device die, and negatively impact coverage, data rate, and battery life of the system or device. Accordingly, there remains a desire for improved thermal resistance and reduced junction temperature in integrated device dies.

### SUMMARY

The innovations described in the claims each have several aspects, no single one of which is solely responsible for its desirable attributes. Without limiting the scope of the claims, some prominent features of this disclosure will now be briefly described.

In one embodiment, an integrated device die is disclosed. The integrated device die comprises: a substrate having a first side and a second side opposite the first side, a heat generating electronic component disposed over the first side of the substrate, a dielectric layer disposed such that the heat generating electronic component is positioned at least partially between the substrate and the dielectric layer, and a thermally conductive structure formed with the dielectric layer and positioned between the substrate and the terminal. A surface of the dielectric layer that faces away the substrate includes a terminal that is electrically connected to the heat generating electronic component and laterally offset from the heat generating electronic component. The substrate and the thermally conductive structure at least partially defines a thermal pathway between the heat generating electronic component and the terminal.

In other embodiments, the heat generating electronic component is a transistor or a resistor. In yet other embodiments, the thermally conductive structure is formed on an active region at or near a surface of the dielectric layer that faces the substrate. In further embodiments, the integrated device die further includes an insulation layer between the substrate and the dielectric layer. In yet further embodiments, the insulation layer can be a buried oxide layer that has a through oxide layer that extends at least partially through a thickness of the buried oxide layer. The through oxide layer can define at least a portion of the thermal pathway.

In additional embodiments, the thermally conductive structure includes metal vias that extend at least partially through a thickness of the dielectric layer. In other embodiments, the thermally conductive structure can include metal traces that extend laterally through a portion of the dielectric layer. In yet other embodiments, the surface of the dielectric layer that faces away the substrate further includes a second terminal laterally offset from the terminal. In further embodiments, the second terminal can be configured to connect to a heatsink. In yet further embodiments, the integrated device die can further include a second thermally conductive structure that is positioned between the second terminal and the substrate.

In other embodiments, the terminal is configured to connect to a heatsink. In yet other embodiments, a thermal conductivity of the substrate is greater than a thermal conductivity of the dielectric layer. In further embodiments the substrate can be a silicon substrate.

In other embodiments, the integrated device die further includes a second thermally conductive structure disposed laterally between the heat generating electronic device and the thermally conductive structure. In yet other embodiments, the thermally conductive structure includes pieces of a conductive material. In further embodiments, a density of the conductive material relative to a material of the dielectric layer in the thermally conductive structure can be more than 50%. In yet further embodiments, the thermally conductive structure includes disconnected portions spaced apart by a portion of the dielectric layer.

In one embodiment, an electronic system is disclosed. The electronic system can include an integrated device die that includes a substrate, a heat generating electronic component coupled to the substrate, a dielectric layer disposed such that the heat generating electronic component is positioned at least partially between the substrate and the dielectric layer, and a thermally conductive structure formed with the dielectric layer. A surface of the dielectric layer that faces away the substrate includes a terminal that is electrically connected to the heat generating electronic component and laterally offset from the heat generating electronic component. The thermally conductive structure is positioned between the substrate and the terminal. The substrate and the thermally conductive structure at least partially defines a thermal pathway between the heat generating electronic component and the terminal. The electronic system can include a heatsink that is coupled with the terminal by way of a thermally conductive material.

In other embodiments, the heat generating electronic component is a transistor or a resistor. In yet other embodiments, the thermally conductive structure is formed on an active region at or near a surface of the dielectric layer that faces the substrate. In still other embodiments, the integrated device die further includes an insulation layer between the substrate and the dielectric layer. In further embodiments, the insulation layer can be a buried oxide layer that has a through oxide layer that extends at least partially through a thickness of the buried oxide layer. The through oxide layer can define at least a portion of the thermal pathway.

In one embodiment, an integrated device die is disclosed that comprises: a substrate having a first side and a second side opposite the first side, a heat generating electronic component disposed over the first side of the substrate, a dielectric layer disposed such that the heat generating electronic component is positioned at least partially between the substrate and the dielectric layer, and a thermally conductive structure formed with the dielectric layer and positioned between the substrate and the terminal. A surface of the dielectric layer that faces away the substrate including a terminal is electrically isolated from the heat generating electronic component. The substrate and the thermally conductive structure at least partially defines a thermal pathway between the heat generating electronic component and the terminal.

In other embodiments, the heat generating electronic component is a transistor or a resistor. In yet other embodiments, the thermally conductive structure is formed on an active region at or near a surface of the dielectric layer that faces the substrate. In further embodiments, the integrated device die further includes an insulation layer between the substrate and the dielectric layer. In yet further embodiments, the insulation layer can be a buried oxide layer that has a through oxide layer that extends at least partially through a thickness of the buried oxide layer. In other embodiments, the through oxide layer can define at least a portion of the thermal pathway.

In additional embodiments, the thermally conductive structure includes metal vias that extend at least partially through a thickness of the dielectric layer. In other embodiments, the thermally conductive structure can also include one or more metal traces that extend laterally through a portion of the dielectric layer. In yet other embodiments, the thermally conductive structure can extend completely through the thickness of the dielectric layer.

In some embodiments, the surface of the dielectric layer that faces away the substrate further includes a second terminal laterally offset from the terminal. In further embodiments, the second terminal can be configured to connect to a heatsink. In yet further embodiments, the integrated device die can further include a second thermally conductive structure positioned between the second terminal and the substrate.

In other embodiments, the terminal is configured to connect to a heatsink. In yet other embodiments, a thermal conductivity of the substrate is greater than a thermal conductivity of the dielectric layer. In further embodiments, the substrate can be a silicon substrate. In yet further embodiments, the integrated device die further includes a second thermally conductive structure connected to a second terminal of the surface of the dielectric layer that faces away the substrate. In still further embodiments, the second terminal can be electrically connected to the heat generating electronic component through an interconnect structure.

In additional embodiments, the thermally conductive structure includes pieces of a conductive material. In further embodiments, a density of the conductive material relative to a material of the dielectric layer in the thermally conductive structure can be more than 50%. In yet further embodiments, the thermally conductive structure includes disconnected portions spaced apart by a portion of the dielectric layer.

In one embodiment, an electronic system is disclosed. The electronic system can include an integrated device die that includes a substrate, a heat generating electronic component coupled to the substrate, a dielectric layer disposed such that the heat generating electronic component is positioned at least partially between the substrate and the dielectric layer, and a thermally conductive structure formed with the dielectric layer. A surface of the dielectric layer that faces away the substrate includes a terminal electrically isolated from the heat generating electronic component. The thermally conductive structure is positioned between the substrate and the terminal. The substrate and the thermally conductive structure at least partially defines a thermal pathway between the heat generating electronic component and the terminal. The electronic system can include a heatsink coupled with the terminal by way of a thermally conductive material.

In other embodiments, the heat generating electronic component is a transistor or a resistor. In yet other embodiments, the thermally conductive structure is formed on an active region at or near a surface of the dielectric layer that faces the substrate. In still other embodiments, the integrated device die further includes an insulation layer between the substrate and the dielectric layer. In further embodiments, the insulation layer can be a buried oxide layer that has a through oxide layer that extends at least partially through a thickness of the buried oxide layer. The through oxide layer can define at least a portion of the thermal pathway.

In one embodiment, an integrated device die is disclosed. The integrated die can comprise a substrate having a first side and a second side opposite the first side; a heat generating electronic component disposed over the first side of the substrate; a dielectric layer disposed such that the heat generating electronic component is positioned at least partially between the substrate and the dielectric layer, a surface of the dielectric layer that faces away the substrate including a terminal electrically isolated from the heat generating electronic component; and a thermally conductive structure formed with the dielectric layer and positioned between the substrate and the terminal, the substrate and the thermally conductive structure at least partially defining a thermal pathway between the heat generating electronic component and the terminal.

In other embodiments, the heat generating electronic component is a transistor or a resistor. In yet other embodiments, the thermally conductive structure is formed on an active region at or near a surface of the dielectric layer that faces the substrate. In a further embodiment, an insulation layer is between the substrate and the dielectric layer. In another embodiment, the insulation layer is a buried oxide layer that has a through oxide layer that extends at least partially through a thickness of the buried oxide layer, the through oxide layer defines at least a portion of the thermal pathway.

In additional embodiments, the thermally conductive structure includes metal vias that extend at least partially through a thickness of the dielectric layer. In yet other embodiments, the thermally conductive structure also includes one or more metal traces that extend laterally through a portion of the dielectric layer, the thermally conductive structure extends completely through the thickness of the dielectric layer. In further embodiments, the surface of the dielectric layer that faces away the substrate further includes a second terminal laterally offset from the terminal, the second terminal is configured to connect to a heatsink. In another embodiment, the integrated device die comprises a second thermally conductive structure positioned between the second terminal and the substrate.

In some embodiments, the terminal is configured to connect to a heatsink. In yet other embodiments, a thermal conductivity of the substrate is greater than a thermal conductivity of the dielectric layer. In yet other embodiments, the substrate is a silicon substrate. In further embodiments, a second thermally conductive structure is connected to a second terminal of the surface of the dielectric layer that faces away the substrate, the second terminal electrically connected to the heat generating electronic component through an interconnect structure.

In additional embodiments, the thermally conductive structure includes pieces of a conductive material, a density of the conductive material relative to a material of the dielectric layer in the thermally conductive structure is more than 50%. In other embodiments, the thermally conductive structure includes disconnected portions spaced apart by a portion of the dielectric layer.

In one embodiment an electronic system is disclosed that comprises: an integrated device die including a substrate, a heat generating electronic component coupled to the substrate, a dielectric layer disposed such that the heat generating electronic component is positioned at least partially between the substrate and the dielectric layer, and a thermally conductive structure formed with the dielectric layer, a surface of the dielectric layer that faces away the substrate including a terminal electrically isolated from the heat generating electronic component, the thermally conductive structure positioned between the substrate and the terminal, the substrate and the thermally conductive structure at least partially defining a thermal pathway between the heat generating electronic component and the terminal; and a heatsink coupled with the terminal by way of a thermally conductive material.

In other embodiments, the heat generating electronic component is a transistor or a resistor. In yet other embodiments, the thermally conductive structure is formed on an active region at or near a surface of the dielectric layer that faces the substrate. In further embodiments, an insulation layer is between the substrate and the dielectric layer. In yet further embodiments, the insulation layer is a buried oxide layer that has a through oxide layer that extends at least partially through a thickness of the buried oxide layer, the through oxide layer defines at least a portion of the thermal pathway.

### BRIEF DESCRIPTION OF THE DRAWINGS

Embodiments of this disclosure will now be described, by way of non-limiting example, with reference to the accompanying drawings.

FIG. 1A shows a schematic cross-sectional side view of a portion of an integrated device die according to an embodiment.

FIG. 1B shows a schematic cross-sectional side view of at least a portion of an integrated device die according to another embodiment.

FIG. 2 shows a schematic cross-sectional side view of at least a portion of an integrated device die according to another embodiment.

FIG. 3 shows a schematic cross-sectional side view of at least a portion of an integrated device die according to another embodiment.

FIG. 4 shows a schematic cross-sectional side view of at least a portion of an integrated device die according to another embodiment.

FIG. 5 shows a schematic cross-sectional side view of at least a portion of an integrated device die according to another embodiment.

FIGS. 6A-6C shows schematic cross-sectional side views of at least portions of integrated device dies according to some embodiments.

FIGS. 7A-7F are schematic cross-sectional side views of portions of three different integrated device dies and simulation results showing junction temperatures Tj and thermal resistances Rth of the three different integrated device dies.

FIGS. 8A-8D are simulation results showing junction temperatures Tj and thermal resistances Rth of four different integrated device dies.

FIGS. 9A-9G are simulation results showing junction temperatures Tj of different integrated device dies.

FIGS. 10A and 10B are simulation results showing junction temperatures Tj of different integrated device dies.

FIGS. 10C and 10D are schematic plan views of portions of the integrated device dies of FIGS. 10A and 10B, respectively.

FIGS. 11A-11C are simulation results showing junction temperatures Tj of different integrated device dies with different locations of thermal terminal structures.

FIGS. 12A and 12B are simulation results showing junction temperatures Tj of different integrated device dies with different locations of thermal terminal structures.

FIG. 13 is a cross-sectional side view of at least a portion of an integrated device die according to an embodiment.

FIG. 14A is a schematic cross-sectional view of a portion of an integrated device die that includes a thermally conductive structure, according to an embodiment.

FIG. 14B is a schematic cross-sectional view of a portion of an integrated device die that includes a thermally conductive structure, according to another embodiment.

FIG. 14C is a schematic cross-sectional view of a portion of an integrated device die that includes a thermally conductive structure, according to another embodiment.

FIGS. 15A-15C are simulation results showing junction temperatures Tj and thermal resistances Rth of integrated device dies each having two G/T terminal structures and two BI terminal structures positioned near the heat sources, and four MA terminal structures positioned remote from the heat sources.

FIGS. 16A-16C compare junction temperatures Tj and thermal resistances Rth of integrated device dies using different number and shape of terminals.

FIG. 17 shows a schematic perspective view of an integrated device die according to an embodiment.

FIG. 18 is a schematic block diagram of a module.

FIG. 19 is a schematic diagram of a wireless communication device.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings. Silicon on insulator die silicon on insulator transistor

An integrated device die, such as a silicon die, a III-V semiconductor die, or a silicon on insulator (SOI) die, can include an electronic component that generates heat or thermal energy. The integrated device die can include a power amplifier or a front-end integrated circuit (FEIC) in the radio frequency (RF) and millimeter wave (mmW) industry. For example, active components such as transistors (e.g., field effect transistors), or passive components (e.g., resistors) can generate heat. The heat generated by the components can cause various issues. For example, the heat can negatively impact reliability of the integrated device die, limit an operating range of the integrated device die, impacts other components in a system or device that the integrated device die is included, limit a modulation order and data rate, negatively impact performance (e.g., lower gain, higher leakage, etc.) of the integrated device die, and negatively impact coverage, data rate, and battery life of the system or device. Various embodiments of integrated device dies disclosed herein can provide improved thermal transfer therewithin to thereby mitigate or prevent such issues from occurring.

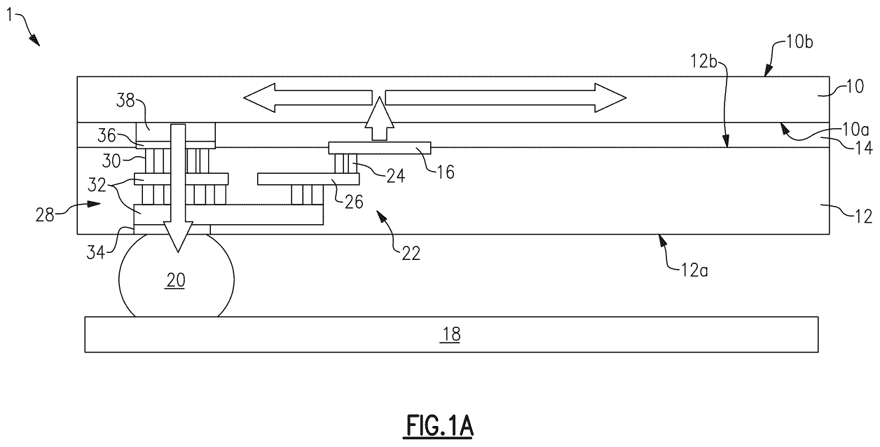

FIG. 1A shows a schematic cross-sectional side view of at least a portion of an integrated device die 1 according to an embodiment. The integrated device die 1 is a silicon on insulator (SOI) die. However, the principles and advantages disclosed herein can be implemented in any flip-chip die. The integrated device die 1 can include a substrate 10 having a first side 10a and a second side 10b opposite the first side 10a, a dielectric layer 12 having a first side 12a and a second side 12b, and an insulation layer 14, such as an oxide layer (e.g., a buried oxide (BOx) layer), between the first side 10a of the substrate 10 and the second side 12b of the dielectric layer 12. The integrated device die 1 can include a heat generating electronic component 16 over the first side 10a of the substrate 10. In the illustrated embodiment, the heat generating electronic component 16 is disposed on the insulation layer 14. The integrated device die 1 can be attached to a heatsink 18 through a bump 20.

The substrate 10 can be a high thermal conductivity material layer that has a relatively high thermal conductivity. A thermal conductivity of the substrate 10 can be greater than a thermal conductivity of the dielectric layer 12. For example, the substrate 10 can include silicon, germanium, or gallium arsenide. As shown in FIG. 1A by arrows, the heat generated by the heat generating electronic component 16 can dissipate through (e.g., dissipate laterally through) the substrate 10.

The heat generating electronic component 16 generates heat during operation of the integrated device die 1. The heat generating electronic component 16 can include an active component such as a transistor (e.g., a field effect transistor (FET)), or a passive component (e.g., a resistor). In some applications, especially in high power applications, the heat generating electronic component 16 may generate significant heat that can degrade the performance of the integrated device die 1. Thermally conductive features disclosed herein can prevent or mitigate the integrated device die 1 from being overheated, or maintain a temperature of the integrated device die 1 within a desired range of temperature.

The dielectric layer 12 can include any suitable dielectric material. In some embodiments, the dielectric layer 12 can be an oxide layer. The integrated device die 1 can include an interconnect structure 22 in the dielectric layer 12 that electrically connects the heat generating electronic component 16 to a terminal 34 on or at the first side 12a of the dielectric layer 12. The interconnect structure 22 can include one or more vias 24 that vertically extends at least partially through a thickness of the dielectric layer 12 and one or more lines or traces 26 that laterally extends at least partially through the dielectric layer 12. In some embodiments, the interconnect structure 22 can provide a ground connection. In some embodiments, the electronic component 16 and the terminal 34 can be laterally offset.

The integrated device die 1 can include a thermally conductive structure 28 in the dielectric layer 12. The thermally conductive structure 28 can include one or more vias 30 that vertically extends at least partially through a thickness of the dielectric layer 12 and one or more lines or traces 32 that laterally extends at least partially through the dielectric layer 12. The thermally conductive structure 28 can be formed on an active region 36 formed at or near a portion of an interface between the dielectric layer 12 and the insulation layer 14. In some embodiments, the active region 36 can be referred to as a silicon pot, a thin film silicon region on which an active device is formed, a doped region (e.g., a P-well or an N-well), or an RX layer. In some embodiments, the materials of the vias 24, 30 and the traces 26, 32 can be the same or similar in thermal conductivity. For example, the vias 24, 30 can be metal vias and the traces 26, 32 can be metal traces. In some embodiments, a thickness of the traces 32 of the thermally conductive structure 28 can be greater than a thickness of the traces 26 of the interconnect structure 22. For example, the thickness of the traces 32 can be more than 1.2, 1.5, 1.7, 2, 3, or 5 times greater than the thickness of the traces 26. The vias 30 and the traces 32 can include a relatively high thermally conductive material. A thermal conductivity of the vias 30 and the traces 32 can be greater than the thermal conductivity of the dielectric layer 12. As shown in FIG. 1A by an arrow, the thermally conductive structure 28 can be configured to dissipate heat vertically from the active region 36 to the terminal 34. The trace 32 that is positioned closest to the terminal 34 can be referred to as a top conductive layer or a top metal.

The terminal 34 is offset laterally relative to the heat generating electronic component 16. Offsetting the terminal 34 laterally relative to the heat generating electronic component 16 can reduce the parasitic effect (e.g., a parasitic capacitive effect) as compared to positioning the terminal 34 directly under the heat generating electronic component 16.

The insulation layer 14 can include any suitable SOI insulation material. In some embodiments, the insulation layer 14 can be a buried oxide (BOx) layer. The insulation layer 14 can at least partially isolate the substrate 10 from the dielectric layer 12. The insulation layer 14 can include a through insulator via or layer 38 that extends at least partially through a thickness of the insulation layer 14. The through insulator layer 38 can include a thermally conductive layer that has a relatively high thermal conductivity. For example, the through insulator layer 38 can include metal, such as copper or tungsten, or a polycrystalline silicon. The through insulator layer 38 can facilitate thermal transfer between the substrate 10 and the thermally conductive structure 28.

The heatsink 18 can include a thermally conductive material that has a relatively high thermal conductivity. For example, the heatsink 18 can be a metal sheet or plate. The bump 20 can include any suitable material. For example, the bump 20 can be a solder bump. In some embodiments, the bump 20 can be replaced with a pillar (e.g., a copper pillar) with a cap (e.g., a solder cap). The heat generated by the heat generating electronic component 16 can be transferred to the heatsink 18 through a thermal pathway at least partially defined by a portion of the insulation layer 14, a portion of the substrate 10, the through insulator layer 38, the active region 36, the thermally conductive structure 28, the terminal 34, and the bump 20.

The terminal 34 with the thermally conductive structure 28 illustrated in FIG. 1A can be referred to as a ground/thermal terminal or G/T terminal structure.

FIG. 1B shows a schematic cross-sectional side view of at least a portion of an integrated device die 1′ according to an embodiment. Unless otherwise noted, the components of FIG. 1B may be similar to or the same as like components disclosed herein, such as those shown in FIG. 1A. The integrated device die 1′ can be generally similar to the integrated device die 1 shown in FIG. 1A except that the integrated device die 1′ includes a thermally conductive structure 40 laterally between the heat generating electronic component 16 and terminal 34.

The thermally conductive structure 40 can include one or more vias 42 that connects an active region 44 positioned at or near a portion of the interface between the dielectric layer 12 and the insulation layer 14, and the trace 26 of the interconnect structure 22. The thermally conductive structure 40 can facilitate thermal transfer of the heat generated by the heat generating electronic component 16. In some embodiments, the insulation layer 14 can include a through insulator layer (not shown) at a portion between an active region 44 and the substrate 10 to further facilitate thermal transfer between the substrate 10 and the active region 44.

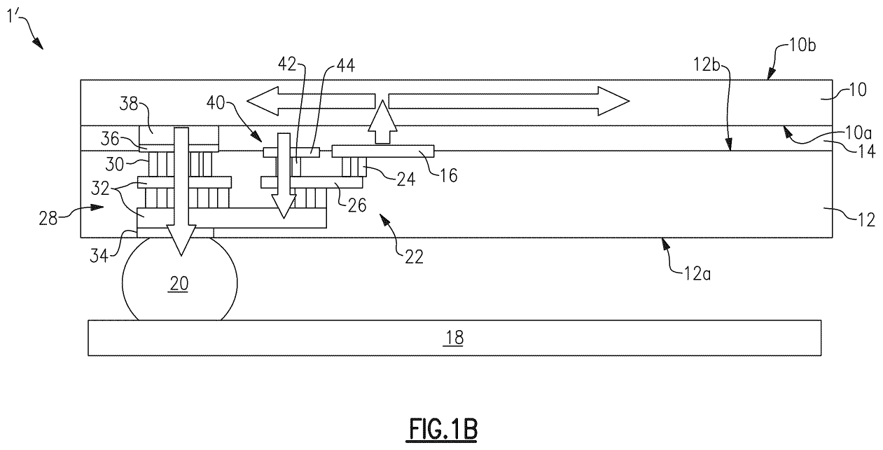

FIG. 2 shows a schematic cross-sectional side view of at least a portion of an integrated device die 2 according to an embodiment. Unless otherwise noted, the components of FIG. 2 may be similar to or the same as like components disclosed herein, such as those shown in FIGS. 1A and 1B.

The integrated device die 2 can include a substrate 10 having a first side 10a and a second side 10b opposite the first side 10a, a dielectric layer 52 having a first side 52a and a second side 52b, and an insulation layer 14, such as an oxide layer (e.g., a buried oxide (BOx) layer), between the first side 10a of the substrate 10 and the second side 52b of the dielectric layer 52. The integrated device die 2 can include a heat generating electronic component 16 over the first side 10a of the substrate 10. In the illustrated embodiment, the heat generating electronic component 16 is disposed on the insulation layer 14. The integrated device die 2 can be attached to a heatsink 18 through a bump 20.

The integrated device die 2 can include a thermally conductive structure 54 in the dielectric layer 52. The thermally conductive structure 54 can include one or more vias 56 that vertically extend at least partially through a thickness of the dielectric layer 52 and one or more lines or traces 58 that laterally extend at least partially through the dielectric layer 52. The thermally conductive structure 54 can be formed on an active region 60 formed at or near a portion of an interface between the dielectric layer 52 and the insulation layer 14. In some embodiments, the active region 60 can be referred to as a silicon pot, thin film silicon region on which an active device is formed, a doped region (e.g., a P-well or an N-well), or an RX layer. For example, the vias 56 can be metal vias and the traces 58 can be metal lines or traces. The vias 56 and the traces 58 can include a relatively high thermally conductive material. A thermal conductivity of the vias 56 and the traces 58 can be greater than the thermal conductivity of the dielectric layer 52. As shown in FIG. 2 by an arrow, the thermally conductive structure 54 can be configured to dissipate heat vertically between the active region 60 to the terminal 62. The trace 58 that is positioned closest to the terminal 62 can be referred to as a top conductive layer or a top metal.

The dielectric layer 52 includes a terminal 62 on or near the first side 52a of the dielectric layer 52. The terminal 62 can be electrically isolated and offset laterally relative to the heat generating electronic component 16. Offsetting the terminal 62 laterally relative to the heat generating electronic component 16 can reduce the parasitic effect (e.g., a parasitic capacitive effect) as compared to positioning the terminal 62 directly under the heat generating electronic component 16.

The insulation layer 14 can include a through insulator via or layer 64 that extends at least partially through a thickness of the insulation layer 14. The through insulator layer 64 can include a thermally conductive layer that has a relatively high thermal conductivity. For example, the through insulator layer 64 can include metal, such as copper or tungsten, or a polycrystalline silicon. The through insulator layer 64 can facilitate thermal transfer between the substrate 10 and the thermally conductive structure 54.

The heat generated by the heat generating electronic component 16 can be transferred to the heatsink 18 through a thermal pathway at least partially defined by a portion of the insulation layer 14, a portion of the substrate 10, the through insulator layer 64, the active region 60, the thermally conductive structure 54, the terminal 62, and the bump 20.

The terminal 62 with the thermally conductive structure 54 and the through insulator layer 14 illustrated in FIG. 2 can be referred to as a through interlayer thermal terminal or BI terminal structure.

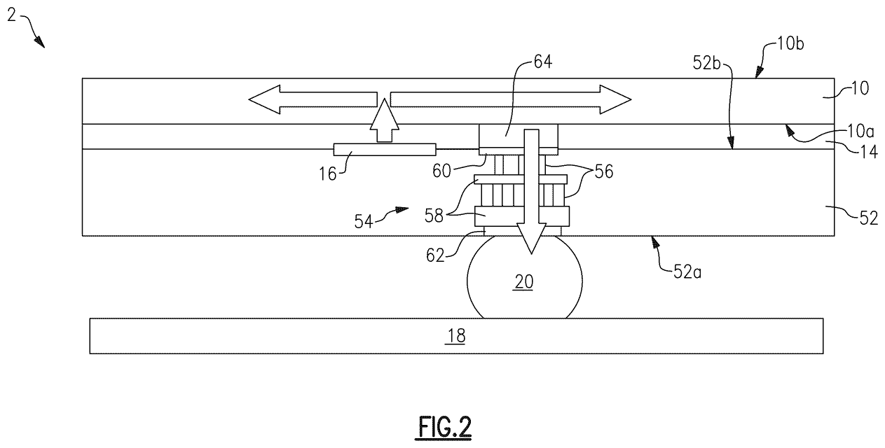

FIG. 3 shows a schematic cross-sectional side view of at least a portion of an integrated device die 3 according to an embodiment. Unless otherwise noted, the components of FIG. 3 may be similar to or the same as like components disclosed herein, such as those shown in FIGS. 1A-2. The integrated device die 3 can be generally similar to the integrated device die 2 shown in FIG. 2 except that the through insulator layer 64 included in the integrated device die 2 is omitted in the integrated device die 3. The heat generated by the heat generating electronic component 16 can be transferred to the heatsink 18 through a thermal pathway at least partially defined by a portion of the insulation layer 14, a portion of the substrate 10, another portion of the insulation layer 14, the active region 60, the thermally conductive structure 54, the terminal 62, and the bump 20. The trace 58 that is positioned closest to the terminal 62 can be referred to as a top conductive layer or a top metal.

The terminal 62 with the thermally conductive structure 54 illustrated in FIG. 3 can be referred to as an active region thermal terminal or RX terminal structure. In some embodiments, the BI terminal structure (see FIG. 2) can provide a more efficient heat dissipating property than the RX terminal structure (see FIG. 3). The improved heat dissipating property may be pronounced when the insulation layer 14 is thicker.

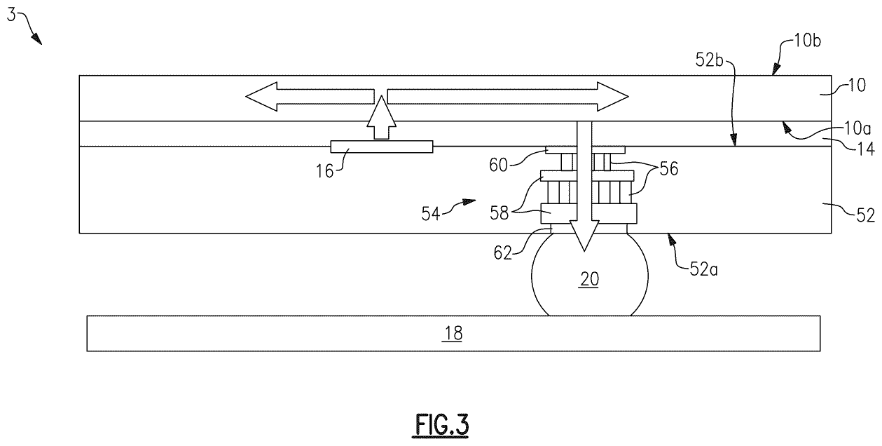

FIG. 4 shows a schematic cross-sectional side view of at least a portion of an integrated device die 4 according to an embodiment. Unless otherwise noted, the components of FIG. 4 may be similar to or the same as like components disclosed herein, such as those shown in FIGS. 1A-3. The integrated device die 4 can be generally similar to the integrated device die 3 shown in FIG. 3. In contrast to the thermally conductive structure 54 of the integrated device die 3, the thermally conductive structure 74 of the integrated device die 4 extends only partially through a thickness of a dielectric layer 72.

The integrated device die 4 can include a substrate 10 having a first side 10a and a second side 10b opposite the first side 10a, a dielectric layer 72 having a first side 72a and a second side 72b, and an insulation layer 14, such as an oxide layer (e.g., a buried oxide (BOx) layer), between the first side 10a of the substrate 10 and the second side 72b of the dielectric layer 72. The integrated device die 4 can include a heat generating electronic component 16 over the first side 10a of the substrate 10. In the illustrated embodiment, the heat generating electronic component 16 is disposed on the insulation layer 14. The integrated device die 4 can be attached to a heatsink 18 through a bump 20.

The thermally conductive structure 74 can include a line or trace 76 that laterally extends at least partially through the dielectric layer 72. The thermally conductive structure 74 can also include one or more vias (not shown) that vertically extends at least partially through the thickness of the dielectric layer 72. The thermally conductive structure 74 can include a material that has a relatively high thermal conductivity. For example, the thermally conductive structure 74 can include a material that has a higher thermal conductivity than a material of the dielectric layer 72.

The dielectric layer 72 includes a terminal 62 on or near the first side 72a of the dielectric layer 72. The terminal 62 can be electrically isolated and offset laterally relative to the heat generating electronic component 16. Offsetting the terminal 62 laterally relative to the heat generating electronic component 16 can reduce the parasitic effect (e.g., a parasitic capacitive effect) as compared to positioning the terminal 62 directly under the heat generating electronic component 16.

The thermally conductive structure 74 can be in contact with the terminal 62. In some embodiments, the terminal 62 can serve as the thermally conductive structure 74. For example, the terminal 62 can have a thickness that allows the terminal 62 to function as the thermally conducive structure 74. The thermally conductive structure 74 can reduce the amount of material of the dielectric layer 72 disposed between the terminal 62 and the insulation layer 14 thereby facilitating thermal transfer between the insulation layer 14 and the terminal 62. In some embodiments, a thickness of the trace 76 can be relatively thick. For example, the thickness of the trace 76 can be greater than 15%, 30%, 50%, 75% of the thickness of the dielectric layer 72. The thickness of the trace 76 can be in a range of 15% to 90%, 30% to 90%, 50% to 90%, 75% to 90% of the thickness of the dielectric layer 72. The heat generated by the heat generating electronic component 16 can be transferred to the heatsink 18 through a thermal pathway at least partially defined by a portion of the insulation layer 14, a portion of the substrate 10, another portion of the insulation layer 14, the dielectric layer 72, the thermally conductive structure 74, the terminal 62, and the bump 20. The trace 76 can be referred to as a top conductive layer or a top metal.

The terminal 62 with the thermally conductive structure 74 illustrated in FIG. 4 can be referred to as a conductive trace thermal terminal or MA terminal structure.

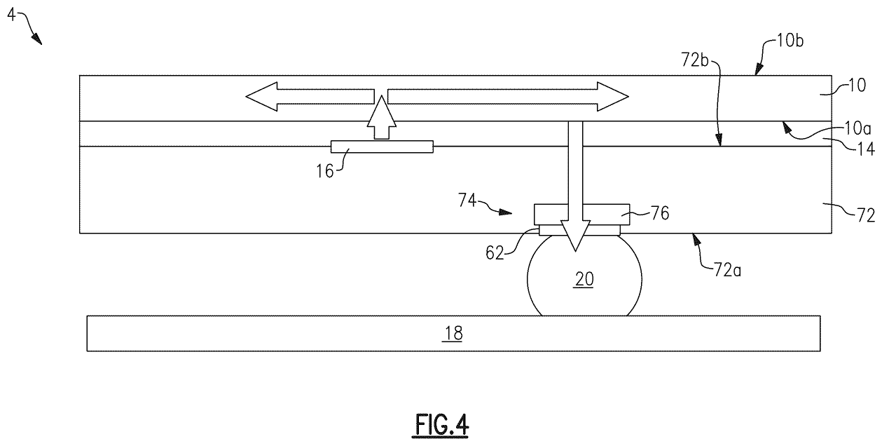

FIG. 5 shows a schematic cross-sectional side view of at least a portion of an integrated device die 5 according to an embodiment. Unless otherwise noted, the components of FIG. 5 may be similar to or the same as like components disclosed herein, such as those shown in FIGS. 1A-4. FIG. 5 shows that the principles and advantages disclosed herein, such as those shown in FIGS. 1A-4, can be implemented in any suitable combinations. For example, the thermally conductive structures 28, 40, 54, 74 can be included in the integrated device die 5 to facilitate heat transfer between the heat generating electronic component 16 and the heatsink 18 thereby reducing a temperature of the integrated device die 5 or maintaining the temperature of the integrated device die 5 below a particular temperature for properly operating the integrated device die 5.

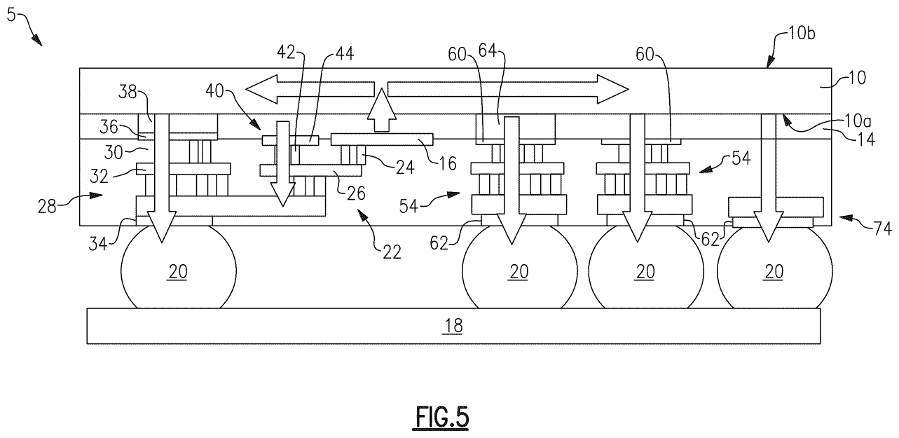

FIGS. 6A-6C shows schematic cross-sectional side views of at least portions of integrated device dies 6a, 6b, 6c according to some embodiments. Unless otherwise noted, the components of FIGS. 6A-6C may be similar to or the same as like components disclosed herein, such as those shown in FIGS. 1A-5. The integrated device dies 6a, 6b, 6c can be generally similar to the integrated device die 4 shown in FIG. 4. The integrated device dies 6a, 6b, 6c can include a substrate 10, a dielectric layer 72, an isolation layer 14 between the substrate 10 and the dielectric layer 72, and a heat generating electronic component 16 formed at or near an interface between the insulation layer 14 and the dielectric layer 72. The integrated device die 6a, 6b, 6c can be coupled to a heatsink 18 through a bump 20 that is attached to a terminal 62. In the integrated device dies 6a, 6b, 6c, the terminal 62 is positioned such that the terminal 62 laterally overlaps the heat generating electronic component 16. The terminal 62 is electrically isolated from or not electrically connected to the heat generating electronic component 16.

Referring to FIG. 6A, the integrated device die 6a can include a thermally conductive structure 80 between the heat generating electronic component 16 and the terminal 62. The thermally conductive structure 80 can include a line or trace 76 in contact (e.g., in direct contact) with the terminal 62, one or more vias 82, one or more traces 84. The traces 76, 84 can laterally extend at least partially through the dielectric layer 72, and the vias 82 can extend at least partially through a thickness of the dielectric layer 72. The trace 76 can be electrically isolated from the vias 82 and the trace 84. For example, the trace 76 and the trace 84 can be spaced apart by a portion of the dielectric layer 72. The thermally conductive structure 80 and the terminal 62 can define a structure that is an example of the MA thermal terminal structure (see FIG. 4).

Referring to FIG. 6B, the integrated device die 6b can include a thermally conductive structure 80′ between the heat generating electronic component 16 and the terminal 62. The thermally conductive structure 80′ can include a line or trace 76 in contact with the terminal 62, one or more vias 86 that extends from the trace 76, and one or more traces 88 connected to the vias 86. The traces 76, 88 can laterally extend at least partially through the dielectric layer 72, and the vias 86 can extend at least partially through a thickness of the dielectric layer 72. The thermally conductive structure 80′ can be electrically isolated from the heat generating electronic component 16. For example, the thermally conductive structure 80′ and the heat generating electronic component 16 can be spaced apart by a portion of the dielectric layer 72. The thermally conductive structure 80′ and the terminal 62 can define a structure that is an example of the MA thermal terminal structure (see FIG. 4).

Referring to FIG. 6C, the integrated device die 6c can include a thermally conductive structure 80″ between the heat generating electronic component 16 and the terminal 62. The thermally conductive structure 80″ can include a line or trace 76 in contact with the terminal 62, one or more vias 90, and one or more traces 92 connected to the vias 90. The traces 76, 92 can laterally extend at least partially through the dielectric layer 72, and the vias 90 can extend at least partially through a thickness of the dielectric layer 72. The trace 76 can be electrically isolated from the vias 90 and the trace 92. For example, the trace 76 and the trace 92 can be spaced apart by a portion of the dielectric layer 72. The thermally conductive structure 80″ and the terminal 62 can define a structure that is an example of the MA thermal terminal structure (see FIG. 4).

The thermally conductive structures 80, 80′, 80″ can include a material that has a relatively high thermal conductivity. For example, the thermally conductive structures 80, 80′, 80″ can include a material that has a higher thermal conductivity than a material of the dielectric layer 72. The thermally conductive structures 80, 80′, 80″ can reduce the distance or the amount of material of the dielectric layer 72 disposed between the terminal 62 and the insulation layer 14 thereby facilitating thermal transfer between the insulation layer 14 and the terminal 62. The heat generated by the heat generating electronic component 16 can be transferred to the heatsink 18 through the insulation layer 14, the thermally conductive structure 80, 80′, 80″ the dielectric layer 72, the thermally conductive structure 74, the terminal 62, and the bump 20.

The thermally conductive structures disclosed herein can include any suitable number of layers. In some embodiments, the thermally conductive structures disclosed herein can include any suitable number of vias and/or traces. For example, the thermally conductive structures disclosed herein can include only traces with no vias, or no traces with only vias. In some embodiments, the trace can be a metal plate that has a thickness equal to or less than a thickness of the dielectric layer of the integrated device die.

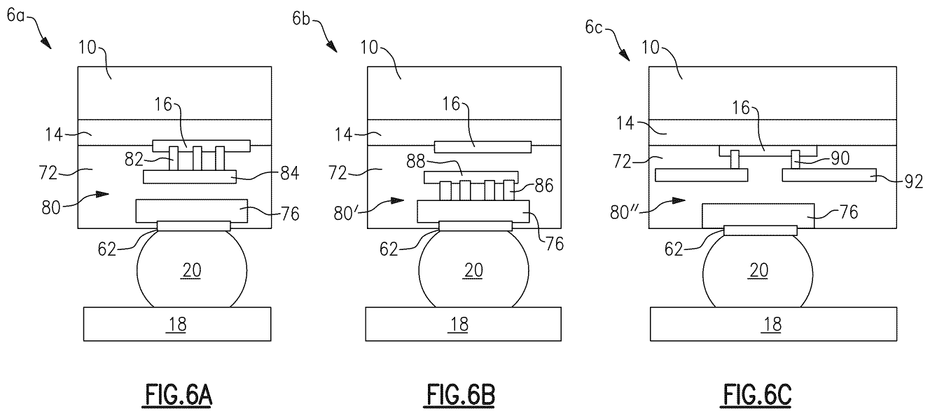

Various embodiments disclosed herein can provide structures for improving heat dissipation in an integrated device die. It has been believed that a terminal of the integrated device die remote and offset laterally from a heat source and isolated by a dielectric material from the heat source does not contribute to sufficiently dissipating heat from the heat source to a heat sink that is connected to the terminal. However, as shown in, for example, FIGS. 7A-7C, it was unexpectedly discovered that a terminal of the integrated device die remote and offset laterally from a heat source and isolated by a dielectric material from the heat source can sufficiently dissipate heat when one or more thermally conductive structure(s) disclosed herein is/are disposed between the terminal and a substrate of the integrated device die.

FIGS. 7A-7F are schematic cross-sectional side views of portions of three different integrated device dies and simulation results showing junction temperatures Tj and thermal resistances Rth of the three different integrated device dies. In the simulation of FIG. 7B, an integrated device die with a terminal 34 that is positioned directly below and electrically connected to a heat source (the heat generating electronic component 16), as shown in FIG. 7A, was used. In the simulation of FIG. 7D, an integrated device die with a terminal 34 that is laterally offset from and electrically connected to a heat source (the heat generating electronic component 16), as shown in FIG. 7C, was used. The heat generating electronic component 16 and the terminal 34 are connected through an interconnect structure 22. The interconnect structure 22 of FIG. 7C includes a trace 26. The trace 26 has a length of about 200 μm and a width of about 70 μm. In the simulation of FIG. 7F, an integrated device die with a terminal 62 and a thermally conductive structure 74 that are laterally offset from and electrically isolated to a heat source (the heat generating electronic component 16), as shown in FIG. 7E, was used.

The junction temperature Tj of the integrated device die of FIG. 7A is 352.6° C. and thermal resistance Rth of the integrated device die of FIG. 7A is 327.6° C./W. The junction temperature Tj of the integrated device die of FIG. 7C is 501.4° C. and thermal resistance Rth of the integrated device die of FIG. 7C is 476.4° C./W. The junction temperature Tj of the integrated device die of FIG. 7E is 512.4° C. and thermal resistance Rth of the integrated device die of FIG. 7E is 487.4° C./W.

The simulation results of FIGS. 7B, 7D, and 7F indicate that the interconnect structure 22 can efficiently transfer thermal energy vertically from the heat generating electronic component 16 to the terminal 34, but a lateral heat conduction in the trace 26 is relatively low. The simulation results of FIGS. 7B, 7D, and 7F indicate that the thermally conductive structure 74 of FIG. 7E can contribute to increasing thermal conductivity in the integrated device die.

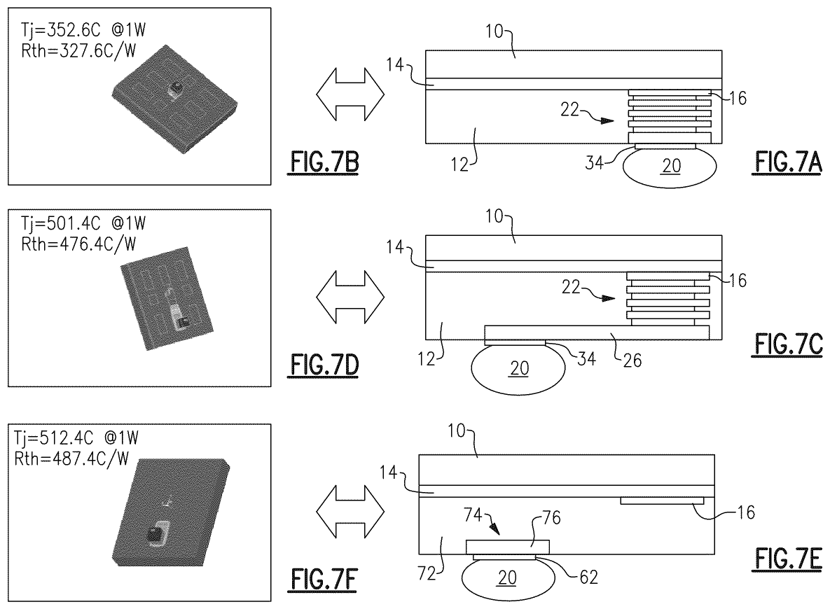

FIGS. 8A-8D are simulation results showing junction temperatures Tj and thermal resistances Rth of four different integrated device dies. The four integrated device dies used in the simulations have generally similar structures except that each of the four integrated device dies had different substrate thicknesses. Each of the four integrated device dies used in the simulations include a dielectric layer, a heat source (an electronic component), and thermal terminals. In FIG. 8A, the integrated device die does not include any underlying substrate. In FIG. 8B, the integrated device die includes an 80 μm silicon substrate that is coupled to the dielectric layer. In FIG. 8C, the integrated device die includes a 150 μm silicon substrate that is coupled to the dielectric layer. In FIG. 8D, the integrated device die includes a 200 μm silicon substrate that is coupled to the dielectric layer.

The junction temperature Tj of the integrated device die of FIG. 8A is 1,057° C. and the thermal resistance Rth of the integrated device die of FIG. 8A is 1,032° C./W. The junction temperature Tj of the integrated device die of FIG. 8B is 118° C. and the thermal resistance Rth of the integrated device die of FIG. 8B is 93° C./W. The junction temperature Tj of the integrated device die of FIG. 8C is 116.6° C. and the thermal resistance Rth of the integrated device die of FIG. 8C is 91.6° C./W. The junction temperature Tj of the integrated device die of FIG. 8D is 116.2° C. and the thermal resistance Rth of the integrated device die of FIG. 8D is 91.2° C./W.

The simulation results of FIGS. 8A-8D indicate that the substrate (e.g., the silicon substrate) can be significant in heat transfer within the integrated device dies. The simulation results of FIGS. 8A-8D indicate that the differences in the junction temperatures Tj and the thermal resistances Rth between the integrated devices of FIGS. 8B-8D are relatively small. The simulation results of FIGS. 7A-8D indicate that the heat from the heat generating electronic component 16 can be transferred through the substrate 10 laterally and through the insulation layer 14, the dielectric layer 72, and the thermally conductive structure 74 vertically to the terminal 62.

Any suitable number of terminals together with any suitable thermally conductive structures and/or through insulator layer can be implemented in an integrated device die for optimizing a desired or proper heat dissipation property of the integrated device die. In some embodiments, location(s) of the terminal(s) can be significant for providing an efficient heat dissipation property of the integrated device die. Selection of the type of thermal terminal structure disclosed herein, such as the G/T terminal structure illustrated in FIG. 1A, the BI terminal structure illustrated in FIG. 2, the RX terminal structure illustrated in FIG. 3, and the MA terminal structure illustrated in FIG. 4, can depend on, for example, the location of the terminal, the target thermal property of the integrated device die, the manufacturing budget, and the foot print availability.

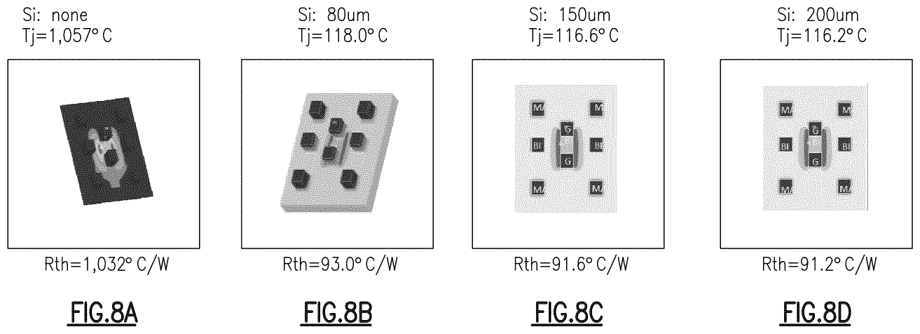

FIGS. 9A-9G are simulation results showing junction temperatures Tj of different integrated device dies. The integrated device dies used in the simulations are generally similar except that the integrated device dies include different numbers and types of the thermal terminal structures. Each of the integrated device dies includes heat sources positioned near the center of the integrated device die. The heat sources can extend laterally lengthwise in a direction parallel with a length of the integrated device die. The heat sources can be spaced apart widthwise along a direction parallel with a width of the integrated device. The lengthwise direction is perpendicular to the widthwise direction.

The integrated device die of FIG. 9A includes two G/T terminal structures and four BI terminal structures positioned near the heat sources. The two G/T terminal structures are positioned widthwise between the four BI terminal structures. The integrated device die of FIG. 9B includes two G/T terminal structures spaced lengthwise and two BI terminal structures spaced widthwise that are positioned near the heat sources, and four MA terminal structures positioned remote from the heat sources. The integrated device die of FIG. 9C includes one G/T terminal structure and two BI terminal structures positioned near the heat sources, and four MA terminal structures positioned remote from the heat sources. The integrated device die of FIG. 9D includes two G/T terminal structures and two MA terminal structures positioned near the heat sources, and four MA terminal structures positioned remote from the heat sources. The integrated device die of FIG. 9E includes two G/T terminal structures and two BI terminal structures positioned near the heat sources. The integrated device die of FIG. 9F includes two G/T terminal structures and four MA terminal structures positioned remote from the heat sources. The integrated device die of FIG. 9G includes two G/T terminal structures positioned near the heat sources.

The simulation results of FIGS. 9A-9G indicate that positioning a thermal terminal structure closer to the heat source can dissipate heat more efficiently than positioning the thermal terminal structure farther away from the heat source. The simulation results of FIGS. 9A-9G indicate that placing more number of thermal terminal structures with an integrated device die can dissipate heat more efficiently generally regardless of the locations and/or the types of the thermal terminal structures.

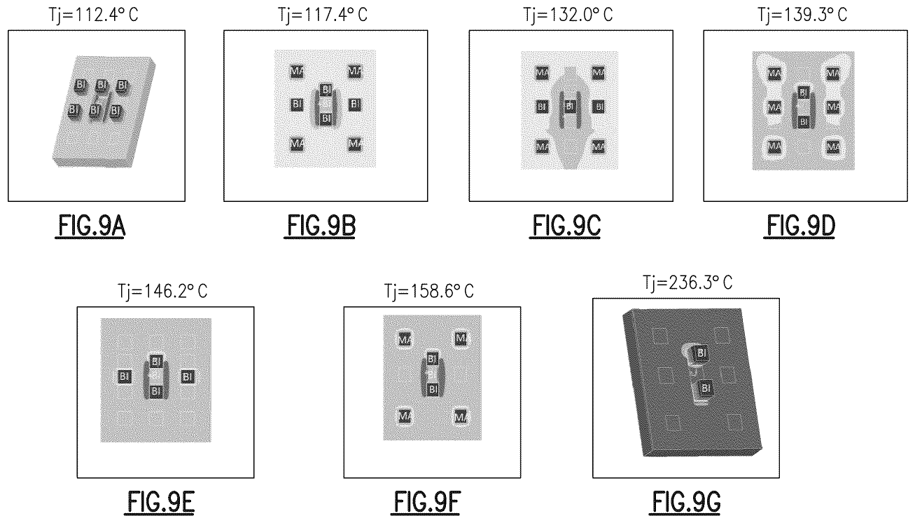

FIGS. 10A and 10B are simulation results showing junction temperatures Tj of two different integrated device dies. FIGS. 10C and 10D are schematic plan views of portions of the integrated device dies of FIGS. 10A and 10B, respectively. The dashed lines between FIGS. 10C and 10D show relative locations of parts of the integrated device dies. The integrated device dies of FIGS. 10A and 10B used in the simulations are generally similar. Each of the integrated device dies includes two G/T terminal structures, two BI terminal structures, and four MA terminal structures. As compared to the integrated device of FIG. 10A, active regions for the two G/T terminal structures of the integrated device of FIG. 10B are increased. Also, the two G/T terminal structures of FIG. 10B are positioned farther way from the heat sources as compared to the G/T terminal structures of FIG. 10A. The simulation results of FIGS. 10A and 10B indicate that, in some embodiments, increasing the active region area can impact more than bringing the thermal terminal structure closer to the heat source.

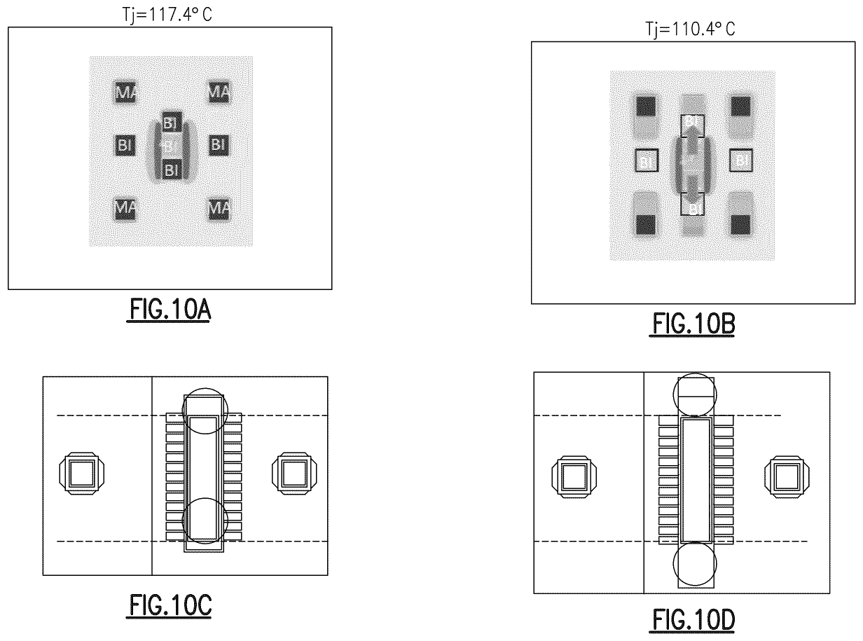

FIGS. 11A-11C are simulation results showing junction temperatures Tj of different integrated device dies with different locations of thermal terminal structures. The simulation results indicate that distances of the thermal terminal structures from the heat sources does not significantly affect the heat dissipation properties of the integrated device dies.

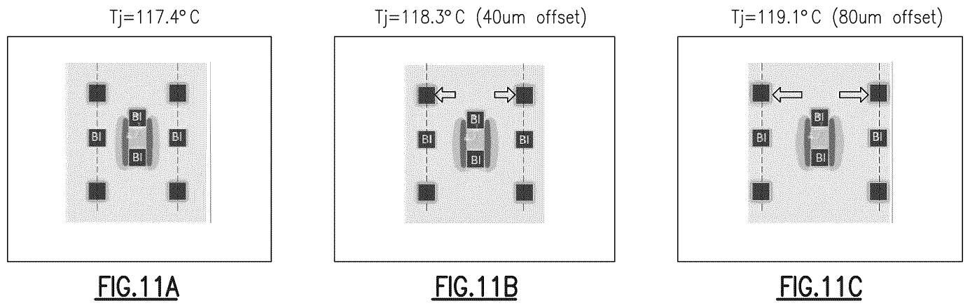

FIGS. 12A and 12B are simulation results showing junction temperatures Tj of two different integrated device dies with different locations of thermal terminal structures. In FIG. 12A, two G/T terminal structures and two BI terminal structures are positioned within a device region 96 of the integrated device die. In FIG. 12B, two G/T terminal structures are positioned within a device region 96 of the integrated device die and two BI terminal structures are positioned outside of the device region 96. The simulation results indicate that the heat generated by the heat sources can be transferred mainly in the device region 96, and placing thermal terminal structures within the device region 96 can dissipate heat from the heat source more efficiently than placing the thermal terminal structures outside of the device region 96.

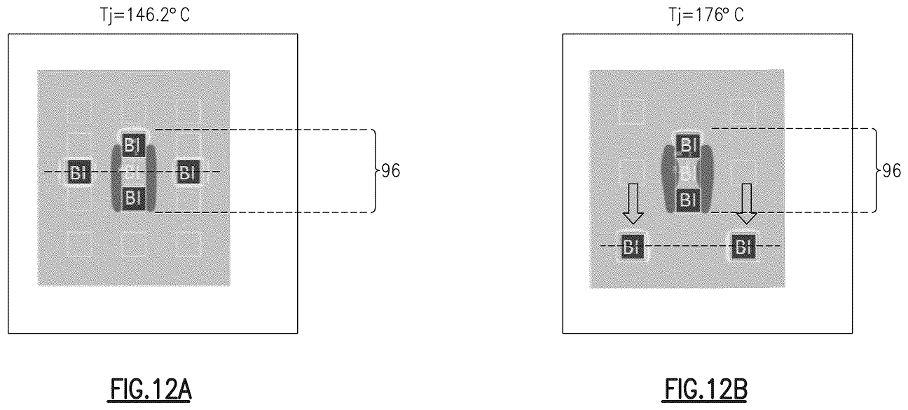

FIG. 13 is a cross-sectional side view of at least a portion of an integrated device die 7 according to an embodiment. Unless otherwise noted, the components of FIG. 7 may be similar to or the same as like components disclosed herein, such as those shown in FIGS. 1A-6C. The integrated device die 7 can include a substrate 10, a dielectric layer 52, an isolation layer 14 between the substrate 10 and the dielectric layer 52, and a heat generating electronic component 16 formed at or near an interface between the insulation layer 14 and the dielectric layer 52. The integrated device die 7 can be coupled to a heatsink 18 through one or more bump(s) 20 that is/are attached to terminal(s) 62. In some embodiments, the terminal 62 is electrically isolated from or not electrically connected to the heat generating electronic component 16.

The integrated device die 7 can include thermally conductive structures 100, 102. The thermally conductive structures 100, 102 can be variations of the thermally conductive structure 54 illustrated in FIG. 3. The thermally conductive structure 100 can be an example of a combination of the RX thermal terminal structure (see FIG. 3) and the MA thermal terminal structure (see FIG. 4). The thermally conductive structure 102 can be an example of the RX thermal terminal structure.

The thermally conductive structures 100, 102 can include one or more vias 56 that vertically extends at least partially through a thickness of the dielectric layer 52 and one or more lines or traces 58 that laterally extends at least partially through the dielectric layer 52. At least portions of the thermally conductive structures 100, 102 can be formed on active regions 60 formed at or near a portion of an interface between the dielectric layer and the insulation layer 14. In some embodiments, the active region 60 can be referred to as a silicon pot, thin film silicon region on which an active device is formed, a doped region (e.g., a P-well or an N-well) or an RX layer. For example, the vias 56 can be metal vias and the traces 58 can be metal lines or traces. The vias 56 and the traces 58 can include a relatively high thermally conductive material. A thermal conductivity of the vias 56 and the traces 58 can be greater than the thermal conductivity of the dielectric layer 52.

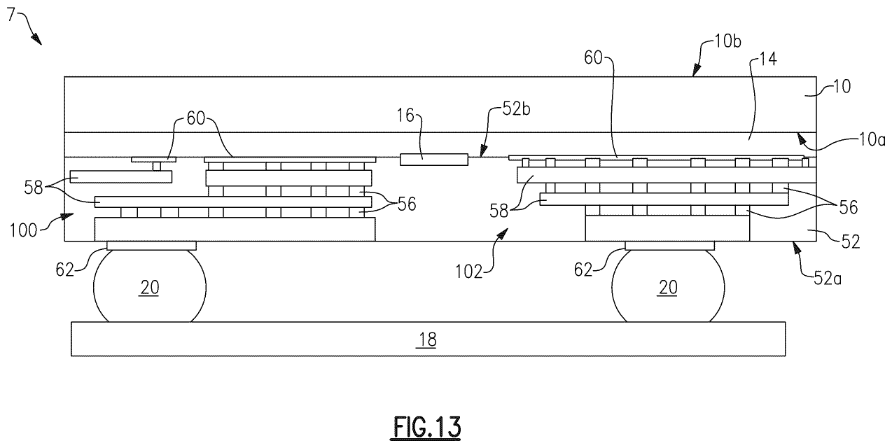

FIG. 14A is a schematic cross-sectional side view of a portion of an integrated device die 8 that includes a thermally conductive structure 110, according to an embodiment. FIG. 14B is a schematic cross-sectional side view of a portion of an integrated device die 8′ that includes a thermally conductive structure 112, according to another embodiment. FIG. 14C is a schematic cross-sectional side view of a portion of an integrated device die 8″ that includes a thermally conductive structure 114, according to another embodiment. The thermally conductive structures 110, 112, 114 can include pieces of thermally conductive materials. For example, the thermally conductive structures 110, 112, 114 can include a metal fill.

In some embodiments, the thermally conductive structure 110 can enable the integrated device die 8 to reduce the thermal resistance Rth by about 11% as compared to a similar integrated device die without the thermally conductive structure 110. In some embodiments, the thermally conductive structure 112 can enable the integrated device die 8′ to reduce the thermal resistance Rth by about 54% as compared to a similar integrated device die without the thermally conductive structure 112. In some embodiments, the thermally conductive structure 114 can enable the integrated device die 8″ to reduce the thermal resistance Rth by about 13% as compared to a similar integrated device die without the thermally conductive structure 114.

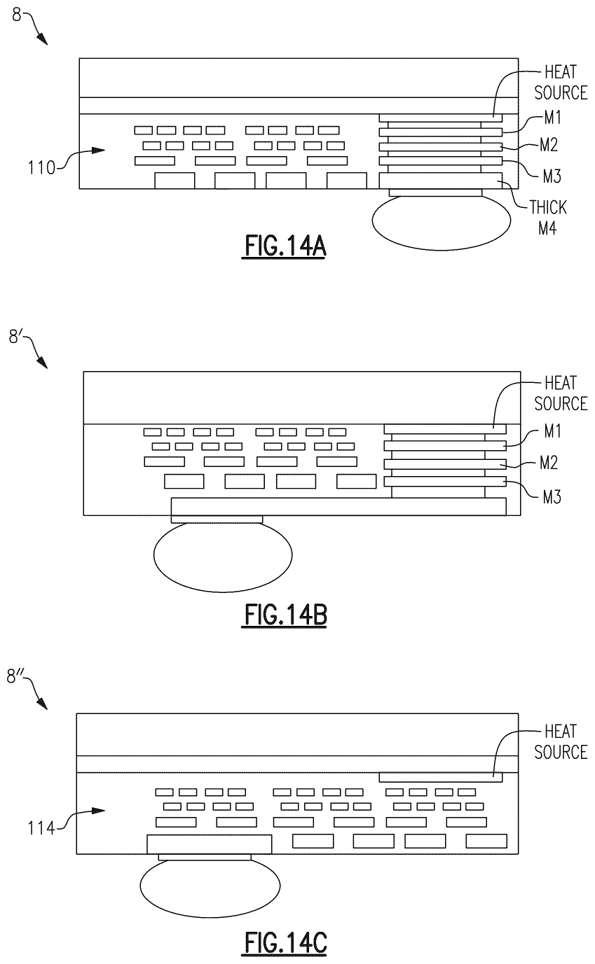

The thermally conductive structures 110, 112, 114 can be implemented in any of the integrated devices disclosed herein. FIGS. 15A-15C compare junction temperatures Tj and thermal resistances Rth of integrated device dies with different fill densities used in integrated device dies.

FIGS. 15A-15C are simulation results showing junction temperatures Tj and thermal resistances Rth of integrated device dies each having two G/T terminal structures and two BI terminal structures positioned near the heat sources, and four MA terminal structures positioned remote from the heat sources. In the integrated devices of FIGS. 15B and 15C, thermally conductive structures similar to the thermally conductive structure 114 shown in FIG. 14C are included for each of the four MA terminal structures positioned remote from the heat sources. A density of the conductive material in the MA terminal structures relative to the material of the dielectric layer is 25% in FIG. 15B and 50% in FIG. 15C. The simulation results of FIGS. 15A-15C indicate that the thermal resistance of FIG. 15B is improved about 1.7% relative to the thermal resistance of FIG. 15A, and the thermal resistance of FIG. 15C is improved about 2.2% relative to the thermal resistance of FIG. 15A.

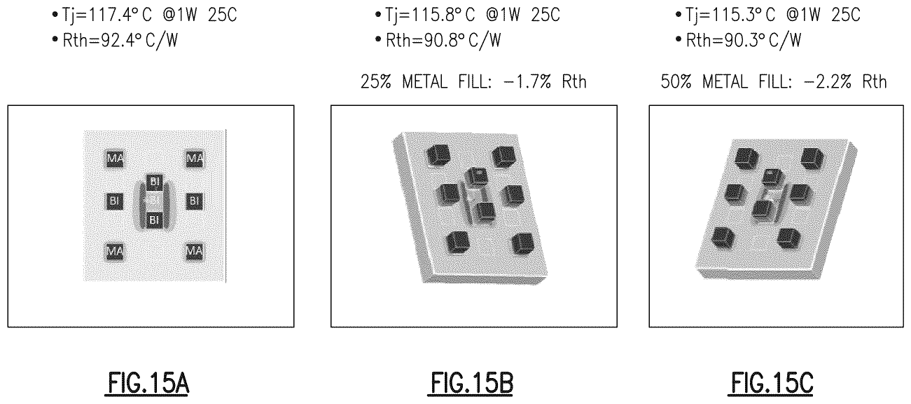

In some embodiments, any one or more of the terminals disclosed herein can include an elongate terminal that has an elongate shape configured to be connected to a heatsink by way of an elongate bump or bar of a conductive material. Such an elongate terminal can increase a contact area between an integrated device die and the heatsink thereby increasing the thermal conductivity between the integrated device die and the heatsink. FIGS. 16A-16C compare junction temperatures Tj and thermal resistances Rth of integrated device dies using different number and shape of terminals.

The integrated device die of FIG. 16A includes one G/T terminal structure and two BI terminal structures positioned near the heat sources, and four MA terminal structures positioned remote from the heat sources. The integrated device die of FIG. 16B includes two G/T terminal structures and two BI terminal structures positioned near the heat sources, and four MA terminal structures positioned remote from the heat sources. The integrated device die of FIG. 16C includes one elongate G/T terminal structure and two BI terminal structures positioned near the heat sources, and four MA terminal structures positioned remote from the heat sources.

The junction temperature Tj of the integrated device die of FIG. 16A is 132° C. and the thermal resistance Rth of the integrated device die of FIG. 8A is 107° C./W. The junction temperature Tj of the integrated device die of FIG. 16B is 117.4° C. and the thermal resistance Rth of the integrated device die of FIG. 8A is 92.4° C./W. The junction temperature Tj of the integrated device die of FIG. 16A is 132° C. and the thermal resistance Rth of the integrated device die of FIG. 8A is 107° C./W. The simulation results of FIGS. 16A-16C indicate that a larger terminal area can improve the junction temperature Tj and the thermal resistance Rth of the integrated device die.

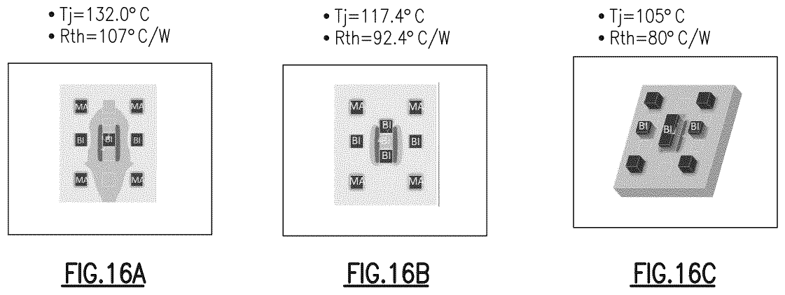

FIG. 17 shows a schematic perspective view of an integrated device die 9 according to an embodiment. The integrated device die 9 includes one elongate G/T terminal structure 120 and two elongate BI terminal structures 122 positioned near the heat sources. In some embodiments, the elongate G/T terminal structure 120 and the elongate BI terminal structures 122 can be disposed in a device region 96 in which the heat sources are positioned. In some embodiments, the elongate G/T terminal structure 120 and the elongate BI terminal structures 122 can extend with the length of the heat sources.

Various embodiments disclosed herein relate to integrated device dies with a thermal terminal structure. An integrated device die can be a flip-chip device die. For example, the integrated deice die can be a carrier on insulator die (e.g., a silicon on insulator (SOI) die). The SOI die can include a substrate (e.g., a silicon substrate), a dielectric layer, and an insulation layer between the substrate and the dielectric layer. The integrated device die includes a heat generating electronic component. For example, the heat generating electronic component can be an active component such as transistors (e.g., field effect transistors) or a passive component (e.g., resistors).

The integrated device die can include the thermal terminal structure that is configured to dissipate heat generated by the heat generating electronic device. In some embodiments, the thermal terminal structure can include a ground/thermal terminal or G/T terminal structure (see FIGS. 1A and 1B), a through interlayer thermal terminal or BI terminal structure (see FIG. 2), an active region thermal terminal or RX terminal structure (see FIG. 3), a conductive trace thermal terminal or MA terminal structure (see FIG. 4). The thermal terminal structure can include a thermally conductive structure formed in or with the dielectric layer. In some embodiments, the thermally conductive structure can include a thermally conductive material. The thermally conductive material of the thermally conductive structure can be provided as a conductive via, a conductive trace or line, a conductive plate, and/or pieces of a conductive material. For example, the thermally conductive material can include copper, aluminum, or tungsten. The integrated device die is configured to couple to an external heat dissipating structure, such as a heatsink. For example, the terminal(s) of the integrated device die can be coupled to the heatsink by way of a conductive adhesive, such as, for example, a solder bump or a copper pillar.

In some embodiments, the substrate can include a III-V material. For example, the substrate can be a silicon substrate, a gallium arsenide substrate, a gallium nitride substrate, a gallium phosphide substrate, or an indium phosphide substrate. The substrate can have a relatively high thermal conductivity. For example, the thermal conductivity of the substrate can be greater than the thermal conductivity of the dielectric layer. In some embodiments, a thickness of the substrate can be in a range between 50 μm and 500 μm, 50 μm and 400 μm, 50 μm and 200 μm, 100 μm and 400 μm, or 100 μm and 200 μm.

The dielectric layer can comprise any dielectric material. For example, the dielectric layer can be an oxide layer, such as a silicon dioxide (SiO₂) layer, or a nitride layer, such as a silicon nitride (SiN) layer. In some embodiments, a thickness of the dielectric layer can be in a range between 5 μm and 20 μm, 5 μm and 15 μm, 5 μm and 10 μm, 10 μm and 20 μm, or 10 μm to 15 μm.

The insulator can comprise any suitable insulating material. For example, the dielectric layer can be a buried oxide (BOx) layer, such as a silicon dioxide (SiO₂) layer.

A diameter of the terminal can be about 75 μm in some embodiments. For example, the diameter can be in a range between 50 μm and 100 μm. In some embodiments, the terminal can have an elongate shape having a long side and a short side that is shorter than the long side. The long side of the elongate terminal can be about 250 μm. For example, the long side can be in a range of about 200 μm and 300 μm.

In some embodiments, the thermal terminal structure can be implemented in a power amplifier or a front-end integrated circuit (FEIC) in the radio frequency (RF) and millimeter wave (mmW) industry. In some embodiments, the thermal terminal structure can be implemented in an acoustic wave device, such as an acoustic wave filter. The acoustic wave filter can include a plurality of resonators arranged to filter a radio frequency signal. Example acoustic wave filters include surface acoustic wave (SAW) filters and bulk acoustic wave (BAW) filters.

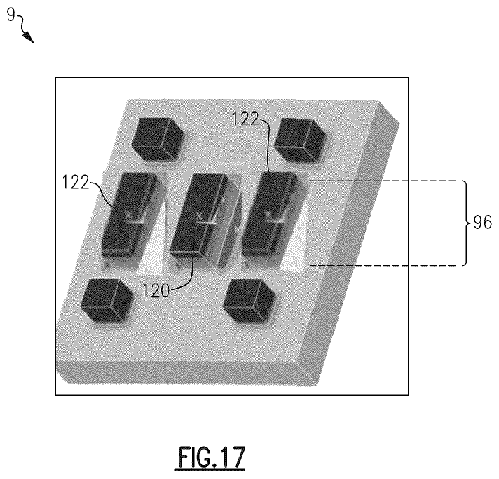

FIG. 18 is a schematic block diagram of a module 210 that includes a power amplifier 212, a radio frequency switch 214, and duplexers 191A to 191N. Any one or more electronic components included in the module 210 can implement the principles and advantages of the thermal terminal structure disclosed herein. For example, the power amplifier 212 can implement the thermal terminal structure disclosed herein. The power amplifier 212 can amplify a radio frequency signal. The radio frequency switch 214 can be a multi-throw radio frequency switch. The radio frequency switch 214 can electrically couple an output of the power amplifier 212 to a selected transmit filter of the duplexers 191A to 191N. One or more filters of the duplexers 191A to 191N can include any suitable number of surface acoustic wave resonators. Any suitable number of duplexers 191A to 191N can be implemented.

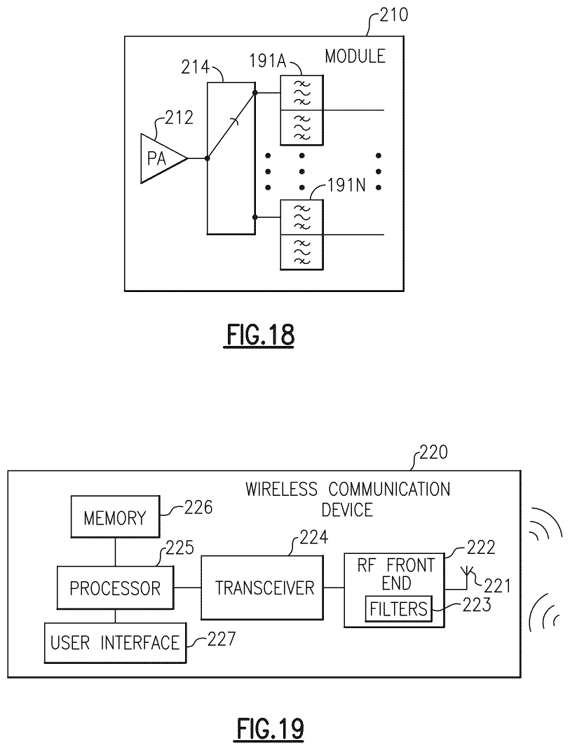

FIG. 19 is a schematic diagram of a wireless communication device 220 that includes filters 223 in a radio frequency front end 222. The filters 223 can include one or more SAW. The wireless communication device 220 can be any suitable wireless communication device. For instance, a wireless communication device 220 can be a mobile phone, such as a smart phone. As illustrated, the wireless communication device 220 includes an antenna 221, an RF front end 222, a transceiver 224, a processor 225, a memory 226, and a user interface 227. The antenna 221 can transmit/receive RF signals provided by the RF front end 222. Such RF signals can include carrier aggregation signals. Although not illustrated, the wireless communication device 220 can include a microphone and a speaker in certain applications. Any one or more electronic components included in the wireless communication device 220 can implement the principles and advantages of the thermal terminal structure disclosed herein.

The RF front end 222 can include one or more power amplifiers, one or more low noise amplifiers, one or more RF switches, one or more receive filters, one or more transmit filters, one or more duplex filters, one or more multiplexers, one or more frequency multiplexing circuits, the like, or any suitable combination thereof. The RF front end 222 can transmit and receive RF signals associated with any suitable communication standards.

The transceiver 224 can provide RF signals to the RF front end 222 for amplification and/or other processing. The transceiver 224 can also process an RF signal provided by a low noise amplifier of the RF front end 222. The transceiver 224 is in communication with the processor 225. The processor 225 can be a baseband processor. The processor 225 can provide any suitable base band processing functions for the wireless communication device 220. The memory 226 can be accessed by the processor 225. The memory 226 can store any suitable data for the wireless communication device 220. The user interface 227 can be any suitable user interface, such as a display with touch screen capabilities.

Aspects of this disclosure can be implemented in various electronic devices. Examples of the electronic devices can include, but are not limited to, consumer electronic products, parts of the consumer electronic products such as packaged radio frequency modules and/or packaged filter components, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. As used herein, the term “approximately” intends that the modified characteristic need not be absolute, but is close enough so as to achieve the advantages of the characteristic. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. An integrated device die comprising:
a substrate having a first side and a second side opposite the first side;
a heat generating electronic component disposed over the first side of the substrate;
a dielectric layer disposed such that the heat generating electronic component is positioned at least partially between the substrate and the dielectric layer, a surface of the dielectric layer that faces away the substrate including a terminal electrically connected to the heat generating electronic component and laterally offset from the heat generating electronic component; and
a thermally conductive structure formed with the dielectric layer and positioned between the substrate and the terminal, the substrate and the thermally conductive structure at least partially defining a thermal pathway between the heat generating electronic component and the terminal.

2. The integrated device die of claim 1 wherein the heat generating electronic component is a transistor or a resistor.

3. The integrated device die of claim 1 wherein the thermally conductive structure is formed on an active region at or near a surface of the dielectric layer that faces the substrate.

4. The integrated device die of claim 1 further comprising an insulation layer between the substrate and the dielectric layer.

5. The integrated device die of claim 4 wherein the insulation layer is a buried oxide layer that has a through oxide layer that extends at least partially through a thickness of the buried oxide layer, the through oxide layer defines at least a portion of the thermal pathway.

6. The integrated device die of claim 1 wherein the thermally conductive structure includes metal vias that extend at least partially through a thickness of the dielectric layer.

7. The integrated device die of claim 6 wherein the thermally conductive structure also includes metal traces that extend laterally through a portion of the dielectric layer.

8. The integrated device die of claim 1 wherein the surface of the dielectric layer that faces away the substrate further includes a second terminal laterally offset from the terminal, the second terminal is configured to connect to a heatsink.

9. The integrated device die of claim 8 further comprising a second thermally conductive structure positioned between the second terminal and the substrate.

10. The integrated device die of claim 1 wherein the terminal is configured to connect to a heatsink.

11. The integrated device die of claim 1 wherein a thermal conductivity of the substrate is greater than a thermal conductivity of the dielectric layer.

12. The integrated device die of claim 11 wherein the substrate is a silicon substrate.

13. The integrated device die of claim 1 further comprising a second thermally conductive structure disposed laterally between the heat generating electronic device and the thermally conductive structure.

14. The integrated device die of claim 1 wherein the thermally conductive structure includes pieces of a conductive material, a density of the conductive material relative to a material of the dielectric layer in the thermally conductive structure is more than 50%.

15. The integrated device die of claim 1 wherein the thermally conductive structure includes disconnected portions spaced apart by a portion of the dielectric layer.

16. An electronic system comprising:
an integrated device die including a substrate, a heat generating electronic component coupled to the substrate, a dielectric layer disposed such that the heat generating electronic component is positioned at least partially between the substrate and the dielectric layer, and a thermally conductive structure formed with the dielectric layer, a surface of the dielectric layer that faces away the substrate including a terminal electrically connected to the heat generating electronic component and laterally offset from the heat generating electronic component, the thermally conductive structure positioned between the substrate and the terminal, the substrate and the thermally conductive structure at least partially defining a thermal pathway between the heat generating electronic component and the terminal; and
a heatsink coupled with the terminal by way of a thermally conductive material.

17. The integrated device die of claim 16 wherein the heat generating electronic component is a transistor or a resistor.

18. The integrated device die of claim 16 wherein the thermally conductive structure is formed on an active region at or near a surface of the dielectric layer that faces the substrate.

19. The integrated device die of claim 16 further comprising an insulation layer between the substrate and the dielectric layer.

20. The integrated device die of claim 19 wherein the insulation layer is a buried oxide layer that has a through oxide layer that extends at least partially through a thickness of the buried oxide layer, the through oxide layer defines at least a portion of the thermal pathway.
